(19) United States
(12) Patent Application Publication
(10) Pub. No.: US 2007/0290724 A1
(43) Pub. Date: Dec. 20, 2007

(54) Comparator circuit

(76) Inventors: Shigeyasu Iwata, Tokyo (JP); Takeshi Ueno, Kawasaki-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/811,752

(22) Filed: Jun. 12, 2007

(30) Foreign Application Priority Data
Jun. 14, 2006 (JP) P2006-165071

(51) Int. Cl. H03K 5/22

(52) U.S. Cl. 327/65

(57) ABSTRACT

According to one embodiment, a comparator circuit includes: a plurality of comparator elements connected in parallel between at least one input signal line and at least one output signal line, each of the comparator elements comparing at least one input potential on the at least one input signal line and outputting comparison result to the at least one output signal line; and a switching device capable of setting each of the comparator elements to either an operation state to compare the at least one input potential or a non-operation state not to compare the at least one input potential, the switching device switching the number of comparator elements which are set to the operation state.

### CROSS-REFERENCE TO RELATED APPLICATIONS

This application is based upon and claims the benefit of priority from Japanese Patent Application No. 2006-165071, filed Jun. 14, 2006, the entire contents of which are incorporated herein by reference.

### BACKGROUND

1. Field

One embodiment of the invention relates to a comparator circuit for comparing input potentials and outputting a comparison result.

2. Description of the Related Art

As a comparator circuit according to a conventional art, there is one disclosed in the Non-patent document 1 cited below. This comparator circuit according to a conventional art is shown in FIG. 6. In this comparator circuit, when a clock signal CLK is 0, transistors M1 and M2 turn to connected states, and a transistor M7 turns to a non-connected state. Thus, input potentials Vᵢₙₚ, Vᵢₙₙ become output potentials Vₒᵤₜₚ, Vₒᵤₜₙ as they are. On the other hand, when the clock signal CLK is 1, the transistors M1 and M2 turn to non-connected states, and the transistor M7 turns to a connected state. At this time, the difference between the input potentials Vᵢₙₚ, Vᵢₙₙ is amplified by a positive feedback amplifying circuit formed by the transistors M3, M4, M5, M6, and the amplified potential is outputted as the output potentials Vₒᵤₜₚ, Vₒᵤₜₙ.

[Non-patent document 1] B. Razavi, A. Wooley “Design Techniques for High-Speed, High-Resolution Comparators,” IEEE J. Solid-State Circuits, vol. 27, no. 12, pp. 1916-1926, December 1992.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary circuit diagram showing a comparator circuit according to an embodiment of the invention;

FIG. 2 is an exemplary circuit diagram showing a comparator element which is a part of the comparator circuit in the embodiment;

FIG. 3 is an exemplary correspondence table showing output signals of NAND circuits and an AND circuit in the embodiment;

FIG. 4 is an exemplary timing chart of a comparator circuit according to a conventional art;

FIG. 5 is an exemplary timing chart of the comparator circuit in the embodiment; and

FIG. 6 is an exemplary circuit diagram showing the comparator circuit according to a conventional art.

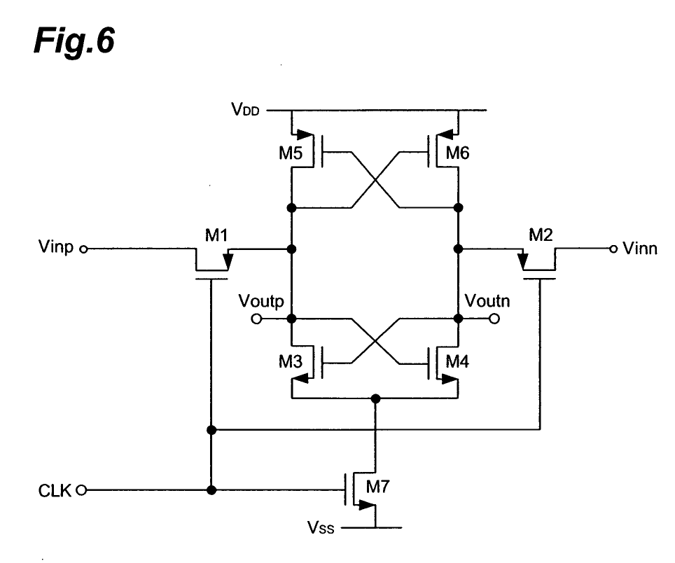

### DETAILED DESCRIPTION

Various embodiments according to the invention will be described hereinafter with reference to the accompanying drawings. In general, according to one embodiment of the invention, a comparator circuit includes: a plurality of comparator elements connected in parallel between at least one input signal line and at least one output signal line, each of the comparator elements comparing at least one input potential on the at least one input signal line and outputting comparison result to the at least one output signal line; and a switching device capable of setting each of the comparator elements to either an operation state to compare the at least one input potential or a non-operation state not to compare the at least one input potential, the switching device switching the number of comparator elements which are set to the operation state.

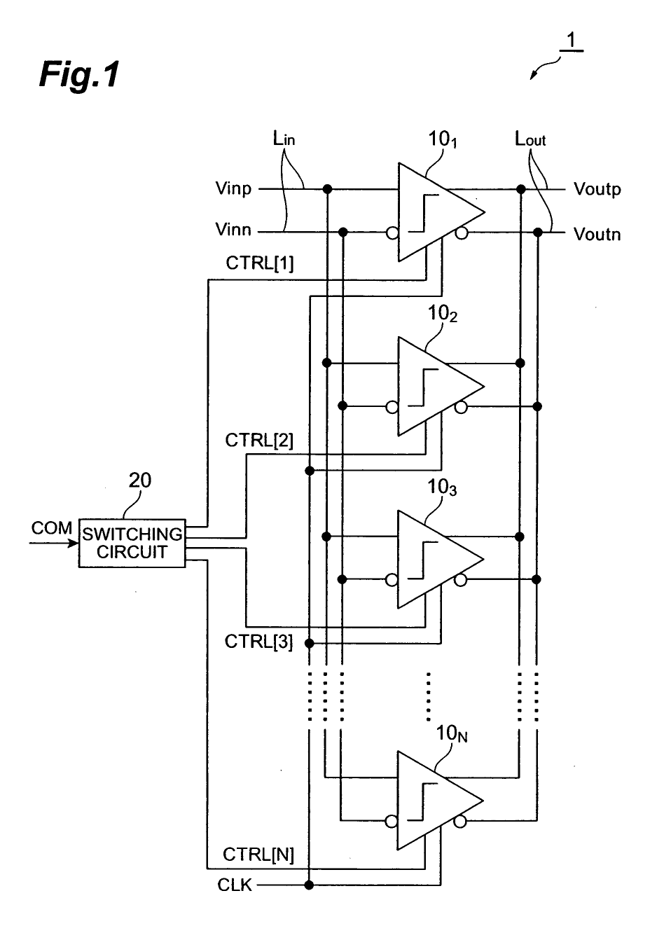

FIG. 1 shows a circuit diagram of a comparator circuit 1 according to this embodiment. The comparator circuit 1 has a large number of comparator elements 10₁ to 10_{N} connected in parallel, and a switching circuit 20 for setting each of the comparator elements 10₁ to 10_{N} to either the operation state or the non-operation state. The plurality of comparator elements 10₁ to 10_{N} are connected in parallel between input signal lines Lᵢₙ and output signal lines Lₒᵤₜ. Further, each of the plurality of comparator elements 10₁ to 10_{N} is connected to the switching circuit 20.

Each of the comparator elements 10₁ to 10_{N} takes in two input potentials Vᵢₙₚ, Vᵢₙₙ via the two input signal lines Lᵢₙ, and compares the magnitude of the two input potentials Vᵢₙₚ, Vᵢₙₙ. Then, each of the comparator elements 10₁ to 10_{N} outputs comparison results of the two input potentials Vᵢₙₚ, Vᵢₙₙ as two output potentials Vₒᵤₜₚ, Vₒᵤₜₙ via the two output signal lines Lₒᵤₜ. Specifically, when the input potential Vᵢₙₚ is larger than the input potential Vᵢₙₙ, a logic high potential (in other words, a power supply voltage V_{DD} or 1) is outputted as the output potential Vₒᵤₜₚ, and a logic low potential (in other words, a ground potential V_{SS} or 0) is outputted as the output potential Vₒᵤₜₙ. On the other hand, when the input potential Vᵢₙₚ is smaller than the input potential Vᵢₙₙ, the logic low potential is outputted as the output potential Vₒᵤₜₚ, and the logic high potential is outputted as the output potential Vₒᵤₜₙ.

The switching circuit 20 is a device to switch the number of comparator elements 10₁ to 10_{N} which are set to the operation state. Specifically, the switching circuit 20 is connected to each of the comparator elements 10₁ to 10_{N}, and outputs control signals CTRL [1] to CTRL [N] to the respective comparator elements 10₁ to 10_{N}. The control signals CTRL [1] to CTRL [N] are signals for setting the comparator elements 10₁ to 10_{N} to either the operation state or the non-operation state. The comparator elements 10₁ to 10_{N} are set to turn to the operation state when the control signals CTRL [1] to CTRL [N] are 0, and the comparator elements 10₁ to 10_{N} are set to turn to the non-operation state when the control signals CTRL [1] to CTRL [N] are 1. Note that the comparator elements 10₁ to 10_{N} may be set to turn to the operation state when the control signals CTRL [1] to CTRL [N] are 1, and the comparator elements 10₁ to 10_{N} may be set to turn to the non-operation state when the control signals CTRL [1] to CTRL [N] are 0.

The switching circuit 20 takes in a command signal COM from the outside, and determines the number of comparator elements 10₁ to 10_{N} to be set to the operation state based on this command signal COM. Specifically, the switching circuit 20 determines whether to set the control signals CTRL [1] to CTRL [N] to be outputted to the respective comparator elements 10₁ to 10_{N} to 0 or 1 based on the command signal COM. Such a command signal COM is a signal to instruct comparison accuracy required for the comparator circuit 1. Note that the switching circuit 20 may be realized by executing a program by an MPU (Micro Processing Unit) or the like, or may be realized using a dedicated circuit performing processing of outputting the control signals.

As described above, when the comparator circuit 1 is constructed by connecting a plurality of comparator elements 10₁ to 10_{N} in parallel, the comparison accuracy of the comparator circuit 1 can be improved. Specifically, the comparison accuracy of the comparator circuit 1 is limited by DC offsets inherent in the comparator elements 10₁ to 10_{N} connected in parallel, but the DC offsets V_{OS}_{_{—}}_{N} of the group of comparator elements 10₁ to 10_{N} connected in parallel correspond to 1/√n of the DC offset V_{OS}_{_{—}}₁ of one comparator element. Thus, by constructing the comparator circuit 1 by connecting a plurality of comparator elements 10₁ to 10_{N} in parallel, the comparison accuracy of the comparator circuit 1 can be improved.

In the comparator circuit 1 of this embodiment, the number n of comparator elements 10₁ to 10_{N} set to the operation state by the switching circuit 20 can be switched. Since the respective DC offsets of the comparator elements disperse to a positive side and a negative side randomly, the larger the number of the comparator elements 10₁ to 10_{N} set to the operation state is increased, the more the respective DC offsets of the comparator elements 10₁ to 10_{N} cancel out each other, and the DC offset as the entire comparator circuit 1 becomes small. On the other hand, the smaller the number of comparator elements 10₁ to 10_{N} set to the operation state, the larger the DC offset as the entire comparator circuit 1 becomes. Specifically, in the comparator circuit 1 of this embodiment, the DC offsets V_{OS}_{_{—}}_{N} (=V_{OS}_{_{—}}₁/√n) can be adjusted and the comparison accuracy with the comparator circuit 1 can be adjusted as the entire comparator circuit 1. Therefore, when high comparison accuracy is required for the comparator circuit 1, the more number of comparator elements 10₁ to 10_{N} are turned to the operation state to thereby meet the requirement of the comparison accuracy. On the other hand, when comparison accuracy is not required so much for the comparison circuit 1, the less number of comparator elements 10₁ to 10_{N} are turned to the non-operation state so as to lower the comparison accuracy of the comparator circuit 1, as well as to reduce consumed power in the comparator circuit 1.

When the comparator circuit 1 is a part of a parallel type A/D converting circuit for converting an analog signal read from a recording medium into a digital signal, the command signal COM to instruct comparison accuracy required for the comparator circuit 1 is preferably a signal showing the type of the recording medium. For example, when the recording medium is a read-only DVD-ROM (Digital Versatile Disc-Read Only Memory), there is a relatively low probability of occurrence of erroneous conversion when an analog signal read from the DVD-ROM is converted into a digital signal. On the other hand, in the case of the DVD-RAM (Digital Versatile Disc-Random Access Memory) capable of rewriting storage contents, there is a relatively high probability of occurrence of erroneous conversion when an analog signal read from the DVD-RAM is converted into a digital signal. Since the probability of occurrence of erroneous conversion when an analog signal is converted into a digital signal differs in this manner depending on the type of a recording medium, the switching circuit 20 may determine the number of comparator elements 10₁ to 10_{N} to be set to the operation state according to the signal indicating the type of a recording medium. Specifically, when the switching circuit 20 takes in a signal COM indicating that it is a recording medium having a low probability of occurrence of erroneous conversion, it can achieve power saving while lowering the comparison accuracy of input potentials moderately by decreasing the number of comparator elements set to the operation state. On the other hand, when the switching circuit 20 takes in a signal COM indicating that it is a recording medium having a high probability of occurrence of erroneous conversion, it can increase the comparison accuracy of input potentials to suppress the erroneous conversion by increasing the number of comparator elements set to the operation state.

Further, when the comparator circuit 1 is a part of a parallel type A/D converting circuit for converting an analog signal read from a recording medium into a digital signal, the command signal COM to instruct comparison accuracy required for the comparator circuit 1 is preferably a signal showing the surface condition of the recording medium. For example, when a surface of a DVD is unclean or scratched, there is a relatively high probability of occurrence of erroneous conversion when an analog signal read from the DVD is converted into a digital signal. On the other hand, when the surface of the DVD is clean or unscratched, there is a relatively low probability of occurrence of erroneous conversion when an analog signal read from the DVD is converted into a digital signal. Since the probability of occurrence of erroneous conversion when an analog signal is converted into a digital signal differs in this manner depending on the surface condition of a recording medium, the comparator circuit 1 may determine the number of comparator elements 10₁ to 10_{N} to be set to the operation state according to the signal indicating the surface condition of a recording medium. Specifically, when the switching circuit 20 takes in a signal COM indicating that the surface condition of a recording medium is good, it can achieve power saving while lowering the comparison accuracy of input potentials moderately by decreasing the number of comparator elements set to the operation state. On the other hand, when the switching circuit 20 takes in a signal COM indicating that the surface condition of a recording medium is bad, it can increase the comparison accuracy of input potentials to suppress the erroneous conversion by increasing the number of comparator elements set to the operation state.

Examples of the above-described recording medium include optical disks such as DVDs (Digital Versatile Disks) and CDs (Compact Disks), magnetic disks such as HDs (Hard Disks) and FDs (Floppy Disks), optical disks such as MOs (Magneto-Optical Disks), and the like. Note that an example in which the comparator circuit 1 is a part of a parallel-type A/D converting circuit is explained, but the application of the comparator circuit 1 is not limited to this; the comparator circuit 1 may be used as a component of another type of circuit.

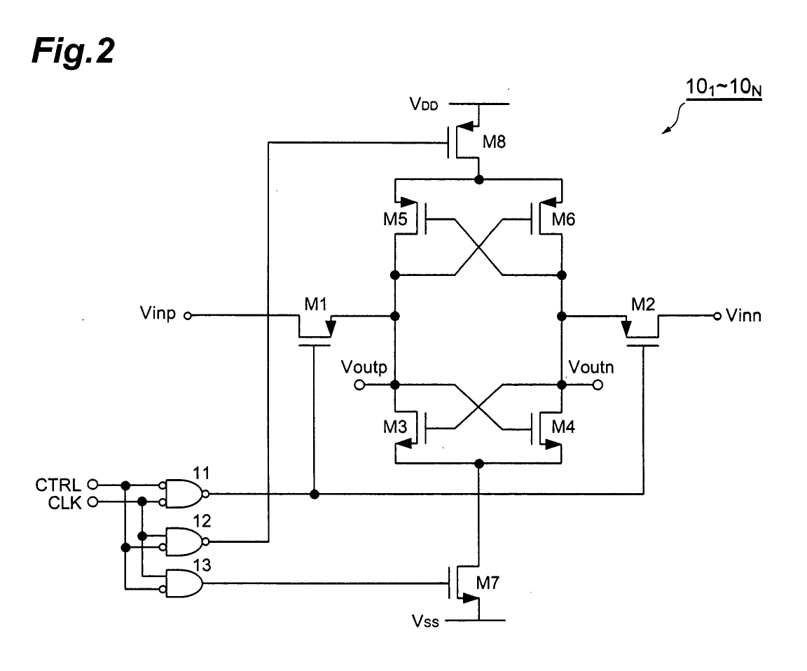

FIG. 2 shows a circuit diagram of each of the comparator elements 10₁ to 10_{N} which is a part of the above-described comparator circuit 1. In the comparator elements 10₁ to 10_{N}, a drain of a transistor M3 and a drain of a transistor M5 are connected with each other, and the transistors M3 and M5 form an inverter. Similarly, a drain of a transistor M4 and a drain of a transistor M6 are connected with each other, and the transistors M4 and M6 form another inverter. Note that in this embodiment, the transistors M3 and M4 are N-channel type transistors, and the transistors M5 and M6 are P-channel type transistors.

The two inverters are connected by cross-coupling. Specifically, a gate of the transistor M3 and the drain of the transistor M4 are connected with each other, and a gate of the transistor M4 and the drain of the transistor M3 are connected with each other. A gate of the transistor M5 and the drain of the transistor M6 are connected with each other, and a gate of the transistor M6 and the drain of the transistor M5 are connected with each other

A source of the transistor M3 and a source of the transistor M4 are connected with each other, and a source of the transistor M5 and a source of the transistor M6 are connected with each other. Here, the transistors M3 and M4 function as an N-channel differential amplifier, and the transistors M5 and M6 function as a P-channel differential amplifier. A circuit formed by the transistors M3 to M6 is a circuit body performing an operation of comparing the input potentials Vᵢₙₚ, Vᵢₙₙ.

The drain of the transistor M3 and the drain of the transistor M5 are connected to an input end for inputting the input potential Vᵢₙₚ. The drain of the transistor M4 and the drain of the transistor M6 are connected to an input end for inputting the input potential Vᵢₙₙ. Further, the drain of the transistor M3 and the drain of the transistor M5 are connected to an output end for outputting the output potential Vₒᵤₜₚ. The drain of the transistor M4 and the drain of the transistor M6 are connected to an output end for outputting the output potential Vₒᵤₜₙ.

The output potentials Vₒᵤₜₚ, Vₒᵤₜₙ outputted from the two output ends are signals indicating a result of comparing the magnitude of the two input potentials Vᵢₙₚ, Vᵢₙₙ. Specifically, when the input potential Vᵢₙₚ is larger than the input potential Vᵢₙₙ, the output potential Vₒᵤₜₚ is the logic high potential V_{DD}, and the output potential Vₒᵤₜₙ is the logic low potential V_{SS}. On the other hand, when the input potential Vᵢₙₚ is smaller than the input potential Vᵢₙₙ, the output potential Vₒᵤₜₚ is the logic low potential V_{SS} and the output potential Vₒᵤₜₙ is the logic high potential V_{DD}.

Note that although the comparator circuit 1 of this embodiment is configured such that the two input potentials Vᵢₙₚ, Vᵢₙₙ are taken in via the two input signal lines Lᵢₙ and the two input potentials Vᵢₙₚ, Vᵢₙₙ are compared with each other, the comparator circuit 1 may be configured such that one input potential Vᵢₙₚ is taken in via one input signal line Lᵢₙ, and the one input potential Vᵢₙₚ is compared with a reference potential V_{ref}. Further, although the comparator circuit 1 of this embodiment is configured such that the two output potentials Vₒᵤₜₚ, Vₒᵤₜₙ are outputted via the two output signal lines Lₒᵤₜ, the comparator circuit 1 may be configured such that the comparison result is indicated by only the output potential Vₒᵤₜₚ outputted via one output signal line Lₒᵤₜ.

A transistor M8 is a power supply switch disposed between the sources of the transistor M5 and transistor M6 and the logic high potential V_{DD}, and turns to a connected state when 0 is applied to its gate to thereby supply the logic high potential V_{DD} to the circuit body M3 to M6, and turns to a non-connected state when 1 is applied to its gate to thereby disconnect the circuit body M3 to M6 from the logic high potential V_{DD}. Further, a transistor M7 is a grounding switch disposed between the sources of the transistor M3 and transistor M4 and the logic low potential V_{SS}, and turns to a connected state when 1 is applied to its gate to thereby ground the circuit body M3 to M6, and turns to a non-connected state when 0 is applied to its gate to thereby disconnect the circuit body M3 to M6 from the logic low potential V_{SS}. Note that in this embodiment, the transistor M7 is an N-channel type transistor, and the transistor M8 is a P-channel type transistor.

The transistor M1 is an input switch disposed between the input end to which the input potential Vᵢₙₚ is inputted and the drains of the transistors M3 and M5, and turns to a connected state when 0 is applied to its gate to thereby supply the input potential Vᵢₙₚ to the circuit body M3 to M6, and turns to a non-connected state when 1 is applied to its gate to thereby disconnect the input end for inputting the input potential Vᵢₙₙ from the circuit body M3 to M6. Further, the transistor M2 is an input switch disposed between the input end to which the input potential Vᵢₙₙ is inputted and the drains of the transistors M4 and M6, and turns to a connected-state when 0 is applied to its gate to thereby supply the input potential Vᵢₙₙ to the circuit body M3 to M6, and disconnects the input end for inputting the input potential Vᵢₙₙ from the circuit body M3 to M6 when 1 is applied to its gate. Note that in this embodiment, the transistors M1 and M2 are P-channel type transistors.

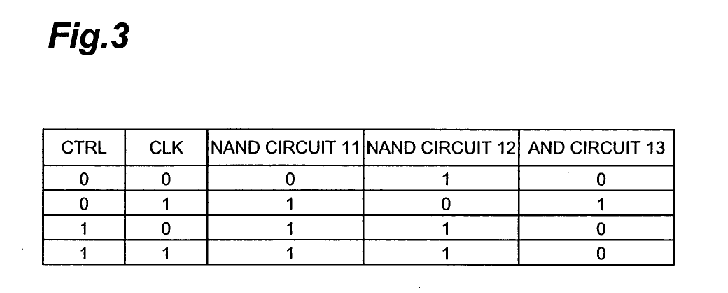

A NAND circuit 11 takes in a control signal CTRL and a clock CLK and outputs either 1 or 0 to the gates of the transistors M1 and M2 for driving the transistors M1 and M2. Further, a NAND circuit 12 takes in the control signal CTRL and the clock signal CLK and outputs either 1 or 0 to the gate of the transistor M8 for driving the transistor M8. Further, an AND circuit 13 takes in the control signal CTRL and the clock signal CLK to output either 1 or 0 to the gate of the transistor M7 to thereby drive the transistor M7. A correspondence table of output signals of the two NAND circuits 11, 12 and the AND circuit 13 corresponding to the control signal CTRL and the clock signal CLK is shown in FIG. 3. Note that each of the NAND circuit 11, the NAND circuit 12, and the AND circuit 13 corresponds to a switch setting device.

Next, the operation of the comparator elements 10₁ to 10_{N} of this embodiment will be described. When the control signal CTRL is 0, the comparator elements 10₁ to 10_{N} are set to the operation state. Now, when the clock signal CLK is 0, the two transistors M1 and M2 for taking the two input potentials Vᵢₙₚ, Vᵢₙₙ into the circuit body M3 to M6 turn to connected states, and hence the two input potentials Vᵢₙₚ, Vᵢₙₙ are supplied to the circuit body M3 to M6. On the other hand, the two transistors M7 and M8 for connecting to the logic high potential V_{DD} and the logic low potential V_{SS} turn to non-connected states, and hence the logic high potential V_{DD} and the logic low potential V_{SS} are not supplied to the circuit body M3 to M6, resulting in that the comparison of the two input potentials Vᵢₙₚ, Vᵢₙₙ is not performed.

When the clock signal CLK changes from 0 to 1 in the above-described state, the two transistors M1 and M2 for taking the two input potentials Vᵢₙₚ, Vᵢₙₙ into the circuit body M3 to M6 change from the connected states to non-connected states, and hence the input end of the two input potentials Vᵢₙₚ, Vᵢₙₙ are disconnected from the circuit body M3 to M6. On the other hand, the two transistors M7 and M8 for connecting to the logic high potential V_{DD} and the logic low potential V_{SS} change from the non-connected states to connected states, and hence the difference between the two input potentials Vᵢₙₚ, Vᵢₙₙ already supplied to the circuit body M3 to M6 is amplified, and a comparison result is outputted as the output potentials Vₒᵤₜₚ, Vₒᵤₜₙ from the output end.

Here, the transistors M3 to M6 function as a latch. Specifically, the transistors M3 to M6 keep retaining a state that one of the output potentials Vₒᵤₜₚ, Vₒᵤₜₙ is the logic high potential V_{DD}, and the other one of them is the logic low potential V_{SS}. Then, when the clock signal CLK returns again from 1 to 0, the two transistors M7 and M8 for connecting to the logic high potential V_{DD} and the logic low potential V_{SS} turn to non-connected states, and hence the retaining of the output potentials Vₒᵤₜₚ, Vₒᵤₜₙ finishes. Note that when the clock signal CLK returns again from 1 to 0, the two transistors M1 and M2 for taking the two input potentials Vᵢₙₚ, Vᵢₙₙ into the circuit body M3 to M6 turn to connected states, and hence the two input potentials Vᵢₙₚ, Vᵢₙₙ are outputted as they are as the output potentials Vₒᵤₜₚ, Vₒᵤₜₙ from the output end.

When the control signal CTRL is 1, the comparator elements 10₁ to 10_{N} are set to non-connected states. Now, when the clock signal CLK is either 0 or 1, the two transistors M1 and M2 for taking the two input potentials Vᵢₙₚ, Vᵢₙₙ into the circuit body M3 to M6 turn to non-connected states, and hence the two input potentials Vᵢₙₚ, Vᵢₙₙ are not supplied to the circuit body M3 to M6. Further, the two transistors M7 and M8 for connecting to the logic high potential V_{DD} and the logic low potential V_{SS} both turn to non-connected states, and hence the circuit body M3 to M6 turns to a disconnected state from the logic high potential V_{DD} and the logic low potential V_{SS}.

In the above-described comparator circuit 1 of this embodiment, the switching circuit 20 sets the comparator elements 10₁ to 10_{N} to non-connected states, and the NAND circuit 12 sets the transistor M8 to a non-connected state, to thereby electrically disconnect the circuit body M3 to M6 from the logic high potential V_{DD}. If the circuit body M3 to M6 were connected to the logic high potential V_{DD} when the comparator elements 10₁ to 10_{N} are set to non-connected states, the differential amplifier M5, M6 connected to the logic high potential V_{DD} is allowed to operate and causes the time constant of the entire circuit to change, and thus the comparison accuracy of the comparator circuit 1 is impaired. In this aspect, as in this embodiment, when the comparator elements 10₁ to 10_{N} are set to non-connected states, the circuit body M3 to M6 of each of the comparator elements 10₁ to 10_{N} is electrically disconnected from the logic high potential V_{DD} with the transistor M8 being a high impedance, which result in that the comparator elements 10₁ to 10_{N} which are set to the non-connected states do not affect the comparison operation of the other comparator elements 10₁ to 10_{N}, and thereby the comparison accuracy as the entire comparator circuit 1 can be maintained.

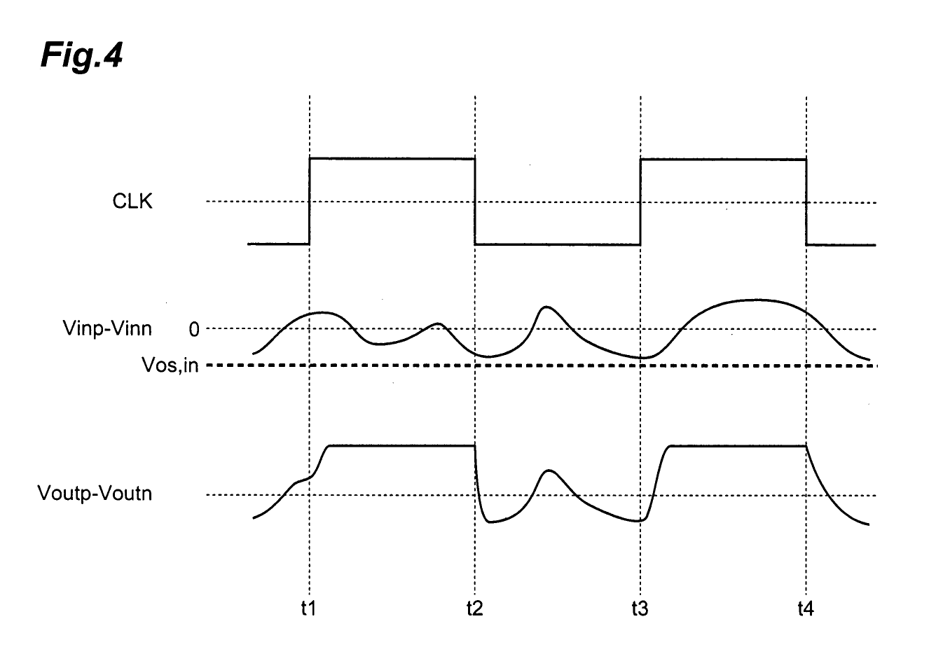

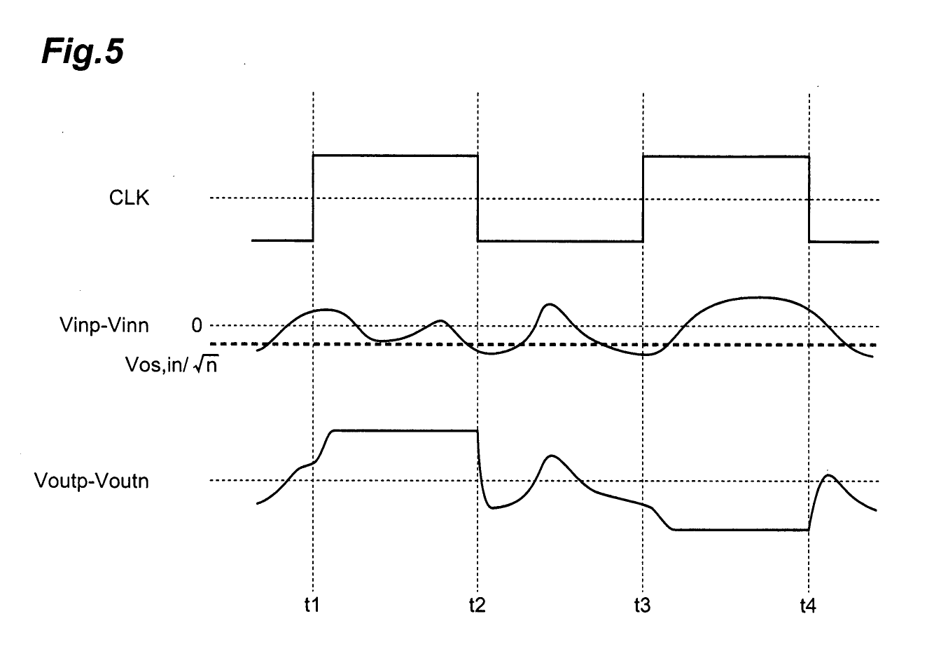

With reference to FIG. 4 and FIG. 5, the effect of the comparator circuit according to the above-described embodiment will be described. FIG. 4 is a timing chart of a comparator circuit according to a conventional art, and FIG. 5 is a timing chart of the comparator circuit according to this embodiment. In the comparator circuit according to a conventional art between time t1 and time t2, according to that the difference Vᵢₙₚ−Vᵢₙₙ between input potentials is 0 or higher, the difference Vₒᵤₜₚ−Vₒᵤₜₙ between output potentials is V_{DD}−V_{SS}. However, between time t3 and time t4, even though the difference Vᵢₙₚ−Vᵢₙₙ between input potentials is 0 or lower, the difference Vₒᵤₜₚ−Vₒᵤₜₙ between output potentials is V_{DD}−V_{SS} since the absolute value of an input conversion offset voltage V_{OS,in} is large. In this point, in the comparator circuit of this embodiment, since it is possible to adjust and reduce the input conversion offset voltage V_{OS,in}/√n, the difference Vₒᵤₜₚ−Vₒᵤₜₙ between output potentials between time t3 and time t4 can be V_{DD}−V_{SS} according to that the difference Vᵢₙₚ−Vᵢₙₙ between input potentials is 0 or lower, and therefore a misjudgment due to DC offsets can be prevented.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A comparator circuit, comprising:
a plurality of comparator elements connected in parallel between at least one input signal line and at least one output signal line, each of said comparator elements configured to compare at least one input potential on the at least one input signal line and to output a comparison result to the at least one output signal line; and
a switching device capable of setting each of said comparator elements to either an operation state to compare the at least one input potential or a non-operation state not to compare the at least one input potential, said switching device to switch the number of comparator elements which are set to the operation state.

2. The comparator circuit according to claim 1,
wherein said switching device is configured to provide each of said comparator elements with a control signal for setting said each comparator element to either the operation state or the non-operation state.

3. The comparator circuit according to claim 1,
wherein said switching device is configured to take in a signal indicating comparison accuracy required for said comparator circuit, and to determine the number of comparator elements to be set to the operation state based on the signal.

4. The comparator circuit according to claim 3,
wherein said comparator circuit is a part of a circuit for converting an analog signal read from a recording medium into a digital signal;
wherein the signal indicating comparison accuracy required for said comparator circuit is a signal indicating a type of the recording medium; and
wherein said switching device is configured to determine the number of comparator elements to be set to the operation state based on the signal indicating the type of the recording medium.

5. The comparator circuit according to claim 3,
wherein said comparator circuit is a part of a circuit for converting an analog signal read from a recording medium into a digital signal;
wherein the signal indicating comparison accuracy required for said comparator circuit is a signal indicating a surface condition of the recording medium; and
wherein said switching device is configured to determine the number of comparator elements to be set to the operation state based on the signal indicating the surface condition of the recording medium.

6. The comparator circuit according to claim 4,
wherein the recording medium is an optical disk, a magnetic disk or a magneto-optical disk.

7. The comparator circuit according to claim 1,
wherein each of said comparator elements includes a circuit body for performing an operation of comparing input potentials on the input signal lines and a switch disposed between a power supply potential and the circuit body, and comprises
a switch setting device for setting the switch connected to comparator elements which are set to the non-operation state to non-connected states, and disconnects the circuit body from the power supply potential.

8. The comparator circuit according to claim 1,
wherein each of said comparator elements includes a circuit body for performing an operation of comparing input potentials on the input signal lines, wherein:
the circuit body has a first P-channel type transistor, a second P-channel type transistor, a first N-channel type transistor, and a second N-channel type transistor;
a source of the first P-channel type transistor and a source of the second P-channel type transistor are connected with each other;
a drain of the first P-channel type transistor and a gate of the second P-channel type transistor are connected with each other, and a drain of the second P-channel type transistor and a gate of the first P-channel type transistor are connected with each other;
the drain of the first P-channel type transistor and a drain of the first N-channel type transistor are connected with each other, and the drain of the second P-channel type transistor and a drain of the second N-channel type transistor are connected with each other;
a first input signal line and a first output signal line are connected to the drain of the first P-channel type transistor, and a second input signal line and a second output signal line are connected to the drain of the second P-channel type transistor;
the drain of the first N-channel type transistor and a gate of the second N-channel type transistor are connected with each other, and the drain of a second N-channel type transistor and the gate of the first N-channel type transistor are connected with each other; and
a source of the first N-channel type transistor and a source of the second N-channel type transistor are connected with each other.

9. The comparator circuit according to claim 8,
wherein each of said comparator elements includes:
an input switch disposed between the circuit body and the input signal lines;
a grounding switch disposed between the circuit body and a ground potential;
a switch setting device for setting, when said each comparator element is set to the operation state, the input switch to a connected state and the grounding switch to a non-connected state according to a clock signal of a logic high potential, and setting the input switch to a non-connected state and the grounding switch to a connected state according to a clock signal of a logic low potential.
